(19) United States
(12) Patent Application Publication
(10) Pub. No.: US 2020/0035924 A1
(43) Pub. Date: Jan. 30, 2020

(54) ORGANIC PHOTODETECTOR

(71) Applicant: Sumitomo Chemical Company Limited, Tokyo (JP)

(72) Inventors: Nir Yaacobi-Gross, Cambridgeshire (GB); Gianluca Bovo, Enfield (GB)

(73) Assignee: Sumitomo Chemical Company Limited, Tokyo (JP)

(21) Appl. No.: 16/495,821

(22) PCT Filed: Mar. 7, 2018
(86) PCT No.: PCT/GB2018/050570

§ 371 Date: Sep. 19, 2019

(30) Foreign Application Priority Data
Mar. 21, 2017 (GB) 1704481.9

(51) Int. Cl. H01L 51/00; C08G 61/12

(52) U.S. Cl. CPC H01L 51/0037; C08G 61/126; H01L 51/0036; H01L 51/0047; H01L 51/0043; C08G 2261/124; H01L 51/4253; C08G 2261/314; C08G 2261/334; C08G 2261/512; C08G 2261/91; H01L 51/0007; H01L 51/0028; C08G 2261/1414

(57) ABSTRACT

An organic photodetector comprising an anode (107), a cathode (103) and a photoactive bulk heterojunction layer (105) comprising an organic electron donor and an organic electron acceptor between the anode and the cathode wherein the anode (107) comprises a material having a work function of at least 5.0 eV from vacuum level. The anode may comprise or consist of a conductive polymer.

### FIELD OF INVENTION

This invention relates to organic photodetectors.

### BACKGROUND OF THE INVENTION

There is an increased interest in the development of organic photosensitive electronic devices as alternatives to inorganic photoelectronic devices because they provide high flexibility and may be manufactured and processed at relatively low costs by using low temperature vacuum deposition or solution processing techniques.

As examples of organic photosensitive electronic devices, organic photovoltaic devices (OPVs) and organic photodetectors (OPDs) may be mentioned. Such an organic photosensitive electronic device may include as a photoactive layer a p-n junction of a donor/acceptor blend which enables the device to convert incident radiation into electrical current.

Examples of p-type (electron donor) materials are conjugated organic oligomers or polymers (e.g. oligomers or polymers of thiophenes, phenylenes, fluorenes, polyacetylenes, benzathiadiazoles and combinations thereof), whereas fullerene and fullerene derivatives (e.g. C₆₀PCBM and C₇₀PCBM) are known n-type (electron acceptor) materials (see e.g. EP 1 447 860 A1 and US 2012/205596).

In the case of an organic photodetector device, the current flowing through the device in the absence of any photons incident on the device, known as dark current, may affect the limit of detection of the device.

US 2005/110007 discloses an organic photodetector comprising an anode having a work function greater than about 4.6 eV, one or more subcells in series, each subcell comprising an organic electron donor layer and an organic electron acceptor layer having a thickness low enough to allow tunneling, an exciton blocking layer and a cathode.

U.S. Pat. No. 9,484,537 discloses an organic photodiode having dual electron blocking layers formed next to the anode.

US 2014/0134781 discloses an organic photovoltaic device comprising an indium-tin oxide (ITO) anode and a hole-transporting layer thereon.

It is an object of the invention to provide organic photodetectors having low dark current.

It is a further object of the invention to provide organic photodetectors having low dark current and high efficiency.

### SUMMARY OF THE INVENTION

The present inventors have found that dark current may be reduced by using an anode having a work function greater than 5.0 eV.

Accordingly, in a first aspect the invention provides an organic photodetector comprising an anode, a cathode and a photoactive layer comprising an organic electron donor and an organic electron acceptor between the anode and the cathode wherein the anode comprises a material having a work function of at least 5.0 eV from vacuum level.

The present inventors have found that dark current of an organic photodetector may be reduced by selecting the anode-electron acceptor LUMO level gap.

Accordingly, in a second aspect the invention provides an organic photodetector comprising an anode, a cathode and a photoactive layer comprising an organic electron donor and an organic electron acceptor between the anode and the cathode wherein the LUMO of the electron acceptor is at least 1.2 eV closer to vacuum than the work function of the anode.

The materials of the organic photodetector including, without limitation, the anode, the cathode, the photoactive layer, the organic electron donor and the organic electron acceptor may be as described anywhere herein with reference to the first aspect.

In a third aspect the invention provides a method of forming an organic photodetector according to the first or second aspect, the method comprising:
applying a formulation comprising the organic electron donor and an organic electron acceptor dissolved in a solvent or solvent mixture over one of the anode and cathode to form a wet film;
drying the wet film to provide the layer comprising the organic electron donor and an organic electron acceptor; and
forming the other of the anode and cathode over the layer comprising the organic electron donor and an organic electron acceptor.

### DESCRIPTION OF THE DRAWINGS

The invention will now be described in more detail with reference to the Figures in which:

FIG. 1 is a schematic illustration of an organic photosensor according to an embodiment of the invention;

FIG. 2A is a graph of current density vs. voltage for a comparative device containing an anode having a work function of less than 5.0 eV and exemplary devices having anode work functions of 5.25 eV and 5.3 eV;

FIG. 2B shows the positive voltage region of the graph of FIG. 2A in more detail;

FIG. 3 is a graph of external quantum efficiency vs. wavelength for the devices described with reference to FIG. 2; and

FIG. 4 is a graph of current density vs. voltage for an exemplary devices having anode work functions of 5.25 eV and 5.7 eV.

### DETAILED DESCRIPTION OF THE INVENTION

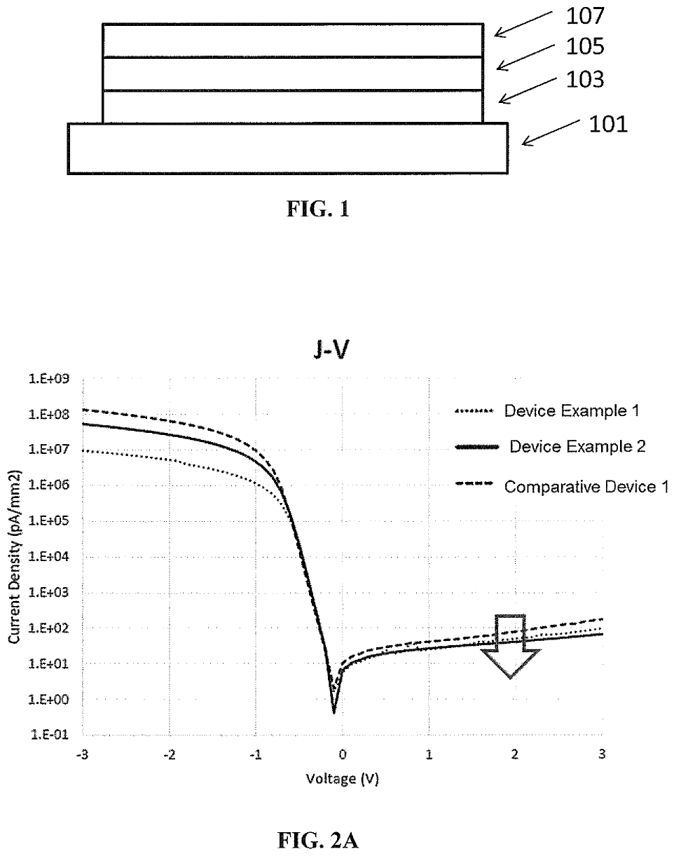

FIG. 1 illustrates an OPD according to an embodiment of the invention. The OPD comprises a cathode 103 supported by a substrate 101, an anode 107 and a photoactive bulk heterojunction layer 105 between the anode and the cathode comprising a mixture of an electron acceptor and an electron donor. Optionally, the bulk heterojunction layer consists of the electron acceptor and electron donor.

The bulk heterojunction layer optionally has a thickness in the range of about 50-3000 nm, preferably 300-1500 nm.

The photoactive layer may have a substantially uniform ratio of electron acceptor and electron donor throughout the thickness of the photoactive layer or the ratio thereof may vary gradually or stepwise throughout the thickness of the photoactive bulk heterojunction layer.

One or more further layers may be provided between the anode and the cathode. A hole-transporting layer may be provided between the anode and the bulk heterojunction layer. An electron-transporting layer may be provided between the cathode and the bulk heterojunction layer. Preferably, the anode consists of a single layer in direct contact with the bulk heterojunction layer.

FIG. 1 illustrates a device in which the bulk heterojunction layer is between the anode and the substrate. The device of FIG. 1 may be formed by depositing the bulk heterojunction layer and anode over the cathode supported on the substrate.

In another arrangement, the bulk heterojunction layer is between the cathode and the substrate. In this case, the anode may be supported on the substrate and the bulk heterojunction layer and the cathode may be formed over the anode.

The anode 103 and the cathode 107 are connected to circuitry which may include a voltage source for applying a reverse bias to the device and a detector (e.g. current meter or readout device, wired in series with the reverse bias voltage source, as detection circuit), for example, to measure the generated photocurrent. Conversion of light incident on the bulk heterojunction layer into electrical current may be detected in reverse bias mode.

The electron donor material has a LUMO that is shallower than the LUMO of the electron acceptor material. Optionally, the gap between the LUMO acceptor and the LUMO donor is at least 0.1 eV.

Optionally, the electron donor material has a LUMO of up to 3.5 eV from vacuum level, optionally 3.0-3.5 eV from vacuum level.

Optionally, the electron donor material has a HOMO level of no more than 5.5 eV from vacuum level.

Optionally, the electron acceptor material has a LUMO level more than 3.5 eV from vacuum level, optionally 3.6-4.0 eV from vacuum level.

Preferably, the LUMO of the electron acceptor is at least 1.2 eV, optionally at least 1.4 eV closer to vacuum than the work function of the anode

HOMO and LUMO levels as described herein are as measured by square wave voltammetry.

The anode preferably comprises or consists of a material having a work function of at least 5.0 eV, preferably at least 5.1 eV, at least 5.2 eV or at least 5.3 eV. The anode may have a work function in the range of 5.0-6.0 eV.

The anode preferably consists of the material having a work function of at least 5.0 eV. If one or more further materials are present in the anode then the material having a work function of at least 5.0 eV preferably makes up at least 60 wt % of the anode.

The material having a work function of at least 5.0 eV may be, without limitation, a metal for example gold; a conductive metal compound for example a conductive metal oxide such as molybdenum, or a conductive polymer. The material is preferably a conductive polymer. Exemplary conductive polymers are fused or unfused polythiophenes, optionally poly(ethylenedioxythiophene) (PEDOT) having a charge-balancing polyanion, optionally polystyrene sulfonate (PSS). The anode may comprise, in addition to the conductive polymer, a charge-neutral derivative of the polyanion, for example a protonated polyacid or a salt thereof, such as polystyrene sulfonic acid (PSSH) or a salt thereof.

The anode may be deposited from an anode formulation comprising or consisting of the material or materials of the anode dissolved or dispersed in one or more liquid materials. Preferably, the only liquid material is water, or the liquid materials comprise water and one or more water-miscible liquid materials, optionally one or more protic or aprotic organic liquid materials, optionally DMSO. The anode formulation may comprise a surfactant. The surfactant may be a non-ionic or ionic surfactant. The surfactant may be a fluorinated surfactant.

Following deposition of the anode formulation, the anode layer may be heated. If the anode formulation is deposited over the bulk heterojunction layer then heating is preferably at a temperature below 150° C., optionally at a temperature in the range of 80-150° C.

The work function of the anode may be affected by factors including, without limitation: the anode material; constituents of an anode formulation other than the anode material, for example the liquids of the anode formulation and any additives present in the anode layer, for example any surfactants; the heating temperature of an anode layer.

If the anode formulation is deposited directly onto the bulk heterojunction layer then the materials of the bulk heterojunction layer preferably undergo little or no dissolution on contact with the liquid material or materials of the anode formulation. Optionally, the bulk heterojunction layer is deposited from a formulation comprising one or more non-polar solvents, optionally a substituted benzene as described in more detail below, and the anode is deposited onto the bulk heterojunction layer from an anode formulation.

It will be understood that the electron donor may be a single electron donor material or a mixture of two or more electron donor materials, and the electron acceptor may consist of a single electron acceptor material or may be a mixture of two or more electron acceptor materials.

The electron acceptor and the electron donor may each independently be a polymeric material or a non-polymeric material.

Preferably, the electron donor is a polymer. Electron donor polymers are optionally selected from conjugated hydrocarbon or heterocyclic polymers including polyacene, polyaniline, polyazulene, polybenzofuran, polyfluorene, polyfuran, polyindenofluorene, polyindole, polyphenylene, polypyrazoline, polypyrene, polypyridazine, polypyridine, polytriarylamine, poly(phenylene vinylene), poly(3-substituted thiophene), poly(3,4-bisubstituted thiophene), polyselenophene, poly(3-substituted selenophene), poly(3,4-bisubstituted selenophene), poly(bisthiophene), poly(terthiophene), poly(bisselenophene), poly(terselenophene), polythieno[2,3-b]thiophene, polythieno[3,2-b]thiophene, polybenzothiophene, polybenzo[1,2-b:4,5-b′]dithiophene, polyisothianaphthene, poly(monosubstituted pyrrole), poly(3,4-bisubstituted pyrrole), poly-1,3,4-oxadiazoles, polyisothianaphthene, derivatives and co-polymers thereof. Preferred examples electron-donor polymers are copolymers of polyfluorenes and polythiophenes, each of which may be substituted, and polymers comprising benzothiadiazole-based and thiophene-based repeating units, each of which may be substituted. The electron donor preferably comprises a repeat unit of formula (I):

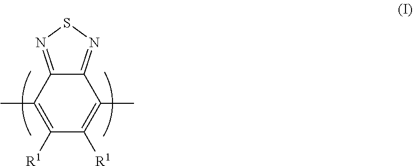

wherein R¹ in each occurrence is independently H or a substituent.

Optionally, each R¹ is independently selected from the group consisting of:

C₁₋₂₀ alkyl wherein one or more non-adjacent, non-terminal carbon atoms of the alkyl group may be replaced with O, S or C═O and wherein one or more H atoms of the C₁₋₂₀ alkyl may be replaced with F; an aryl or heteroaryl group, preferably phenyl, which may be unsubstituted or substituted with one or more substituents; and fluorine.

Substituents of an aryl or heteroaryl group are optionally selected from F, CN, NO₂ and C₁₋₂₀ alkyl wherein one or more non-adjacent, non-terminal carbon atoms of the alkyl group may be replaced with O, S or C═O.

By “non-terminal” as used herein is meant a carbon atom other than the methyl group of a linear alkyl (n-alkyl) chain and the methyl groups of a branched alkyl chain.

A polymer comprising a repeat unit of formula (I) is preferably a copolymer comprising one or more co-repeat units.

The one or more co-repeat units may comprise or consist of one or more of C₆₋₂₀ monocyclic or polycyclic arylene repeat units which may be unsubstituted or substituted with one or more substituents; 5-20 membered monocyclic or polycyclic heteroarylene repeat units which may be unsubstituted or substituted with one or more substituents.

The one or more co-repeat units may have formula (II):

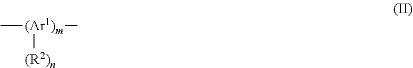

wherein Ar¹ in each occurrence is an arylene group or a heteroarylene group; m is at least 1; R² is a substituent; R² in each occurrence is independently a substituent; n is 0 or a positive integer; and two groups R² may be linked to form a ring.

Optionally, each R² is independently selected from the group consisting of a linear, branched or cyclic C₁₋₂₀ alkyl wherein one or more non-adjacent, non-terminal C atoms of the C₁₋₂₀ alkyl may be replaced with O, S, COO or CO.

Two groups R² may be linked to form a C₁₋₁₀ alkylene group wherein one or more non-adjacent C atoms of the alkylene group may be replaced with O, S, COO or CO.

Optionally, m is 2.

Optionally, each Ar¹ is independently a 5 or 6 membered heteroarylene group, optionally a heteroarylene group selected from the group consisting of thiophene, furan, selenophene, pyrrole, diazole, triazole, pyridine, diazine and triazine, preferably thiophene.

Optionally, the repeat unit of formula (II) has formula (IIa):

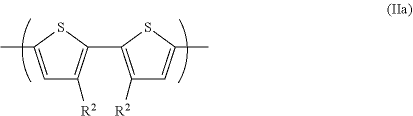

Optionally, the groups R² are linked to form a 2-5 membered bridging group. Optionally, the bridging group has formula —O—C(R¹⁶)₂— wherein R¹⁶ in each occurrence is independently H or a substituent. Substituents R¹⁶ are optionally selected from C₁₋₂₀ alkyl. Preferably each R¹⁶ is H.

An electron-accepting polymer, an electron-donating polymer or an anode polymer as described herein may have a polystyrene-equivalent number-average molecular weight (Mn) measured by gel permeation chromatography in the range of about 1×10³ to 1×10⁸, and preferably 1×10³ to 5×10⁶. The polystyrene-equivalent weight-average molecular weight (Mw) of the polymers described herein may be 1×10³ to 1×10⁸, and preferably 1×10⁴ to 1×10⁷

Preferably, the electron acceptor is a non-polymeric compound, more preferably a fullerene.

The fullerene may be a C₆₀, C₇₀, C₇₆, C₇₈ and C₈₄ fullerene or a derivative thereof including, without limitation, PCBM-type fullerene derivatives (including phenyl-C61-butyric acid methyl ester (C₆₀PCBM), TCBM-type fullerene derivatives (e.g. tolyl-C61-butyric acid methyl ester (C₆₀TCBM)), and ThCBM-type fullerene derivatives (e.g. thienyl-C61-butyric acid methyl ester (C₆₀ThCBM).

Fullerene derivatives may have formula (III):

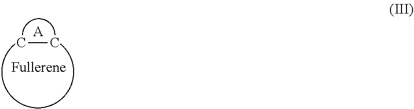

wherein A, together with the C—C group of the fullerene, forms a monocyclic or fused ring group which may be unsubstituted or substituted with one or more substituents.

Exemplary fullerene derivatives include formulae (IIIa), (IIIb) and (IIIc):

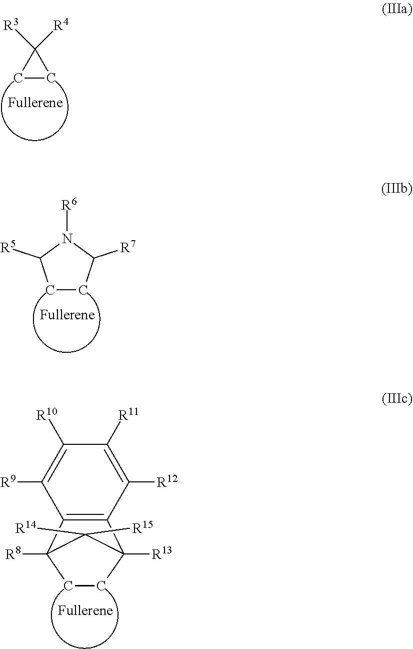

wherein R³-R¹⁵ are each independently H or a substituent.

Substituents R³-R¹⁵ are optionally and independently in each occurrence selected from the group consisting of aryl or heteroaryl, optionally phenyl, which may be unsubstituted or substituted with one or more substituents; and C₁₋₂₀ alkyl wherein one or more non-adjacent, non-terminal C atoms may be replaced with O, S, CO or COO and one or more H atoms may be replaced with F.

Substituents of aryl or heteroaryl, where present, are optionally selected from C₁₋₁₂ alkyl wherein one or more non-adjacent, non-terminal C atoms may be replaced with O, S, CO or COO and one or more H atoms may be replaced with F.

At least one of the anode and cathode electrodes is transparent so that light incident on the device may reach the bulk heterojunction layer.

The or each transparent electrode preferably has a transmittance of at least 70%, optionally at least 80%, to wavelengths in the range of 400-900 nm.

Optionally, the cathode comprises

[symbol]

The device may be formed by forming the bulk heterojunction layer over one of the anode and cathode supported by a substrate and depositing the other of the anode or cathode over the bulk heterojunction layer.

The substrate may be, without limitation, a glass or plastic substrate. The substrate is transparent if, in use, incident light is to be transmitted through the substrate and the electrode supported by the substrate.

The substrate supporting one of the anode and cathode may or may not be transparent if, in use, incident light is to be transmitted through the other of the anode and cathode.

The cathode optionally comprises or consists of one or more metals, for example silver or Ag:Mg alloy, or a conductive metal oxide.

Optionally, the cathode comprises or consists of a layer of conductive metal oxide, optionally ITO, wherein a cathode modification layer is provided between the cathode and the bulk heterojunction layer.

The bulk heterojunction layer may be formed by any process including, without limitation, thermal evaporation and solution deposition methods.

Preferably, the bulk heterojunction layer is formed by depositing a formulation comprising the acceptor material and the electron donor material dissolved or dispersed in a solvent or a mixture of two or more solvents. The formulation may be deposited by any coating or printing method including, without limitation, spin-coating, dip-coating, roll-coating, spray coating, doctor blade coating, slit coating, dispense printing, ink jet printing, screen printing, gravure printing and flexographic printing.

In dispense printing, a continuous flow of ink is deposited from a nozzle positioned at a defined distance from the substrate. A desired pattern may be created by a relative movement of the nozzle and the substrate.

By controlling the nozzle dispense rate (solution flow rate), the pattern density (line spacing), the nozzle movement speed (line speed) as well as the ink concentration, the uniformity of the photoactive layer film may be tuned.

The one or more solvents of the formulation may optionally comprise or consist of benzene substituted with one or more substituents selected from chlorine, C₁₋₁₀ alkyl and C₁₋₁₀ alkoxy wherein two or more substituents may be linked to form a ring which may be unsubstituted or substituted with one or more C₁₋₆ alkyl groups, optionally toluene, xylenes, trimethylbenzenes, tetramethylbenzenes, anisole, indane and its alkyl-substituted derivatives, and tetralin and its alkyl-substituted derivatives.

The formulation may comprise a mixture of two or more solvents, preferably a mixture comprising at least one benzene substituted with one or more substituents as described above and one or more further solvents. The one or more further solvents may be selected from esters, optionally alkyl or aryl esters of alkyl or aryl carboxylic acids, optionally a C₁₋₁₀ alkyl benzoate or benzyl benzoate.

The formulation may comprise further components in addition to the electron acceptor, the electron donor and the one or more solvents. As examples of such components, adhesive agents, defoaming agents, deaerators, viscosity enhancers, diluents, auxiliaries, flow improvers colourants, dyes or pigments, sensitizers, stabilizers, nanoparticles, surface-active compounds, lubricating agents, wetting agents, dispersing agents and inhibitors may be mentioned.

The organic photodetector as described herein may be used in a wide range of applications including, without limitation, detecting the presence and/or brightness of ambient light and in a sensor comprising the organic photodetector and a light source. The photodetector may be configured such that light emitted from the light source is incident on the photodetector and changes in wavelength and/or brightness of the light may be detected. The sensor may be, without limitation, a gas sensor, a biosensor, an X-ray imaging device, a motion sensor (for example for use in security applications) a proximity sensor or a fingerprint sensor.

An organic photodetector as described herein may be used in a wide range of applications including, without limitation, detecting the presence and/or brightness of ambient light and in a sensor comprising at least one organic photodetector as described herein and at least one light source. The photodetector may be configured such that light emitted from a light source is incident on the photodetector and changes in wavelength and/or brightness of the light may be detected. An array of photodetectors as described herein may be configured to detect light emitted from a single light source or from two or more light sources. The sensor may be, without limitation, a gas sensor, a biosensor, X-ray imaging or a motion sensor, for example a motion sensor used in security applications, a proximity sensor or a fingerprint sensor.

### EXAMPLES

### Work Function, HOMO and LUMO Measurements

Work function values as described herein are as measured by an AC2 photoelectron yield spectrometer from Riken Keiki Instruments. Measurements are made in an ambient air environment.

HOMO and LUMO values herein are as measured by square wave voltammetry at room temperature.

In square wave voltammetry, the current at a working electrode is measured while the potential between the working electrode and a reference electrode is swept linearly in time. The difference current between a forward and reverse pulse is plotted as a function of potential to yield a voltammogram.

The apparatus to measure HOMO or LUMO energy levels by SWV may comprise a cell containing tertiary butyl ammonium perchlorate or tertiary butyl ammonium hexafluorophosphate in acetonitrile; a glassy carbon working electrode; a platinum counter electrode and a leak free Ag/AgCl reference electrode. Ferrocene is added directly to the existing cell at the end of the experiment for calculation purposes where the potentials are determined for the oxidation and reduction of ferrocene versus Ag/AgCl using cyclic voltammetry (CV).

Apparatus:
CHI 660D Potentiostat
3 mm diameter glassy carbon working electrode
Leak free Ag/AgCl reference electrode
Pt wire auxillary or counter electrode
0.1M tetrabutylammonium hexafluorophosphate in acetonitrile

Method
The sample is dissolved in Toluene (3 mg/ml) and spun at 3000 rpm directly on to the glassy carbon working electrode

LUMO=4.8-E ferrocene (peak to peak average)−E reduction of sample (peak maximum)

HOMO=4.8-E ferrocene (peak to peak average)+E oxidation of sample (peak maximum)

A typical SWV experiment runs at 15 Hz frequency; 25 mV amplitude and 0.004V increment steps. Results are calculated from 3 freshly spun film samples for both the HOMO and LUMO data.

All experiments are run under an Argon gas purge.

### Device Examples 1 and 2

Devices having the following structure were prepared:

### Cathode/Donor:Acceptor Layer/Anode

A glass substrate coated with silver and a layer of indium-tin oxide (ITO) was treated with polyethyleneimine (PETE) to modify the work function of the ITO. A composition of Donor Polymer 1, illustrated below, and fullerene acceptor C70 PCBM 1:2 w/w was applied by wire bar coating onto the PEIE to form a photoactive layer having a thickness of about 900 nm. The anode was fanned over the photoactive layer by spin-coating a layer of a hole-transporting material supplied by Heraeus, Inc. as set out in Table 1 followed by annealing at 130° C.

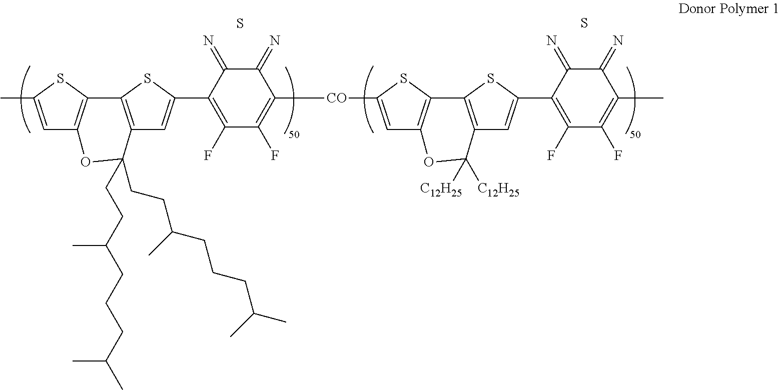

TABLE 1

| Device | Hole transport material | Work function (eV) |
|---|---|---|
| Comparative Device 1 | HTL Solar | 4.9 |
| Device Example 1 | HIL E100 | 5.25 |
| Device Example 2 | HIL E200 | 5.3 |

HIL E100 and HIL E200 as supplied were diluted with an equal volume of water and 2 wt % of Capstone FS-30 surfactant, available from DuPont, before spin-coating. 5 wt % of DMSO was added to HTL Solar before spin-coating.

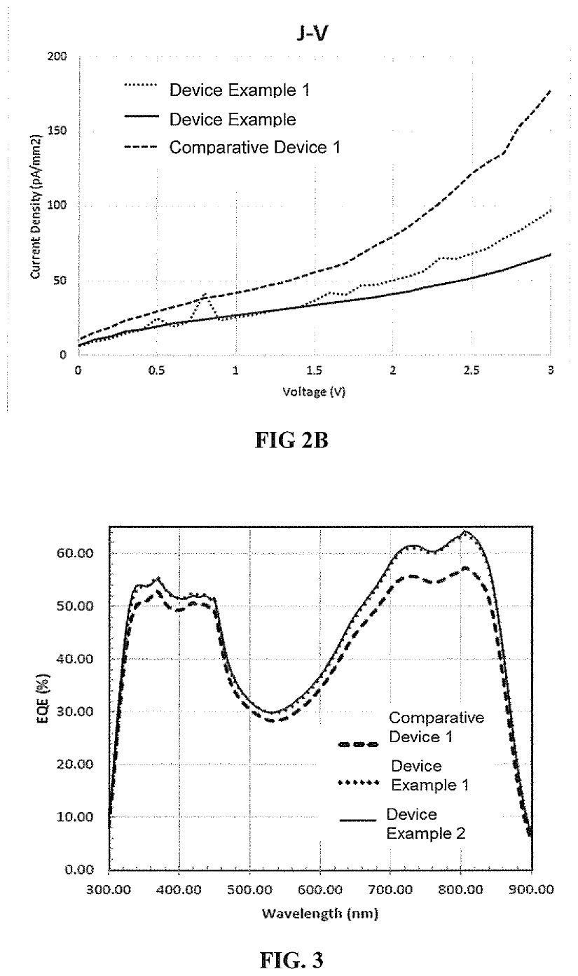

Dark current of Device Examples 1 and 2 and Comparative Device 1 were measured. As shown in FIGS. 2A and 2B, the dark current is much higher for Comparative Device 1 than for either Device Example 1 or 2. The arrow in FIG. 2A denotes increasing anode work function for the measured devices.

External quantum efficiencies of the devices is shown in FIG. 3. Surprisingly, Device Examples 1 and 2 have higher external quantum efficiencies than Comparative Device 1.

### Device Examples 3 and 4

Devices were prepared as described with reference to Device Examples 1 and 2 except that fullerene acceptor C70 IPH was used in place of C70 PCBM in a weight ratio of 1:1.7 and the donor/acceptor layer was formed to a thickness of 1.1-1.2 microns and hole transporting materials as set out in Table 2 were used to form the anode in which HIL E100 was supplied by Heraeus, Inc. and AQ1300 was supplied by Solvay. HIL E100 as supplied was modified as described in Device Examples 1 and 2 before spin-coating. AQ1300 was used as supplied.

TABLE 2

| Device | Hole transport material | Work function (eV) |
|---|---|---|
| Device Example 3 | HIL E100 | 5.25 |
| Device Example 4 | AQ1300 | 5.7 |

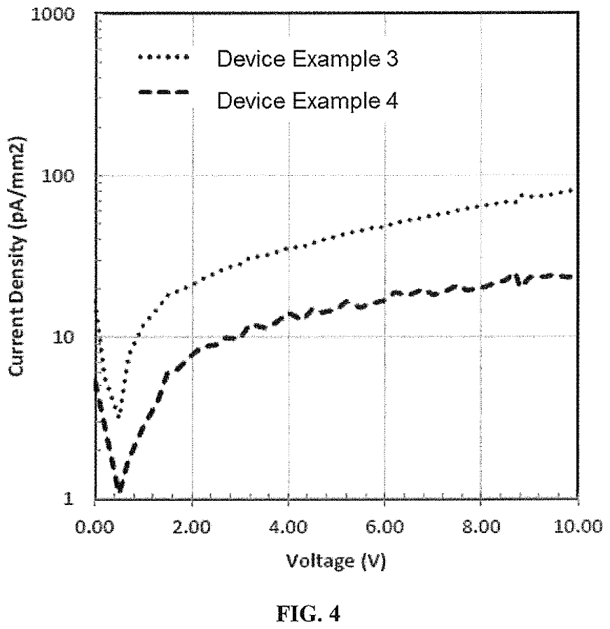

With reference to FIG. 4, dark current of Device Example 4 is lower than for Device Example 3 in which the anode has a shallower HOMO.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. An organic photodetector comprising an anode, a cathode and a photoactive layer comprising an organic electron donor and an organic electron acceptor between the anode and the cathode wherein the anode comprises a material having a work function of at least 5.0 eV from vacuum level.

2. An organic photodetector according to claim 1 wherein the anode is in direct contact with the photoactive layer.

3. An organic photodetector according to claim 2 wherein the anode is a single layer in direct contact with the photoactive layer.

4. An organic photodetector according to claim 1 wherein the anode comprises a material having a work function of at least 5.1 eV from vacuum level.

5. An organic photodetector according to claim 1 wherein the anode comprises a material having a work function of at least 5.2 eV from vacuum level.

6. An organic photodetector according to claim 1 wherein the anode comprises a material having a work function of at least 5.3 eV from vacuum level.

7. An organic photodetector according to claim 1 wherein the anode comprises a conductive polymer.

8. An organic photodetector according to claim 7 wherein the conductive polymer is a fused or unfused polythiophene.

9. An organic photodetector according to claim 8 wherein the conductive polymer is poly(ethylenedioxythiophene) with a charge-balancing polyanion.

10. An organic photodetector according to claim 1 wherein the LUMO of the electron acceptor is at least 1.2 eV closer to vacuum than the work function of the anode.

11. An organic photodetector according to claim 10 wherein the LUMO of the electron acceptor is at least 1.4 eV closer to vacuum than the work function of the anode.

12. An organic photodetector according to claim 1 wherein the electron acceptor is a fullerene or a derivative thereof.

13. An organic photodetector according to claim 12 wherein the electron acceptor is a fullerene derivative of formula (III): 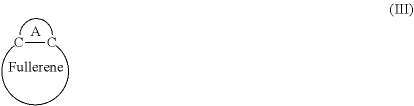
wherein A, together with the C—C group of the fullerene, forms a monocyclic or fused ring group which may be unsubstituted or substituted with one or more substituents.

14. An organic photodetector according to claim 13 wherein the fullerene derivative of formula (III) is selected from formulae (IIIa), (IIIb) and (IIIc): 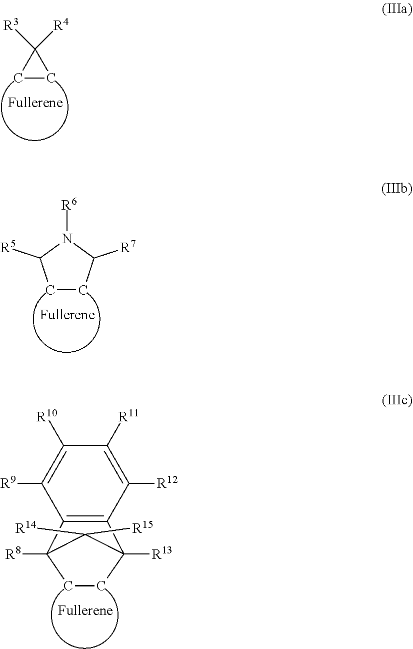
wherein R³-R¹⁵ are each independently H or a substituent.

15. An organic photodetector according to claim 1 wherein the electron donor is a polymer; and
wherein the electron donor is a conjugated polymer.

16. (canceled)

17. An organic photodetector according to claim 16 wherein the polymer comprises a repeat unit of formula (I): 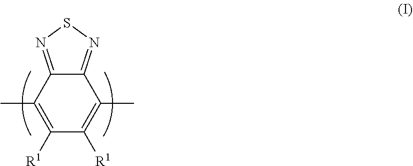
wherein R¹ in each occurrence is independently H or a substituent.

18. An organic photodetector comprising an anode, a cathode and a photoactive layer comprising an organic electron donor and an organic electron acceptor between the anode and the cathode wherein the LUMO of the electron acceptor is at least 1.2 eV closer to vacuum than the work function of the anode.

19. A method of forming an organic photodetector according to any one of the preceding claims, the method comprising:
applying a formulation comprising the organic electron donor and an organic electron acceptor dissolved in a solvent or solvent mixture over one of the anode and cathode to form a wet film;
drying the wet film to provide the photoactive layer comprising the organic electron donor and an organic electron acceptor; and
forming the other of the anode and cathode over the layer comprising the organic electron donor and an organic electron acceptor.

20. A sensor comprising a light source and an organic photodetector according to claim 1.

21. A method of detecting light comprising measurement of a photocurrent generated by light incident on an organic photodetector according to claim 1.
